(19) United States
(12) Patent Application Publication
(10) Pub. No.: US 2006/0046481 A1
(43) Pub. Date: Mar. 2, 2006

(54) Manufacturing methods and electroless plating apparatus for manufacturing wiring circuit boards

(76) Inventor: Takuya Tokuda, Komaki (JP)

Correspondence Address: STITES & HARBISON PLLC, 1199 NORTH FAIRFAX STREET, SUITE 900, ALEXANDRIA, VA, 22314, US

(21) Appl. No.: 11/197,312

(22) Filed: Aug. 5, 2005

(30) Foreign Application Priority Data
May 25, 2005 (JP) 2005-152816
Aug. 26, 2004 (JP) 2004-247093

(51) Int. Cl. H01L 21/44

(52) U.S. Cl. 438/687

(57) ABSTRACT

A manufacturing method for wiring circuit boards enhances product yield and promotes uniform electrical characteristics among the products by reducing fluctuations in the thickness of the electroless Cu plating film. In a plating bath (53) containing an electroless Cu plating liquid (EPL), wiring circuit board workpieces (100) are held in an upright position so as to leave gaps permitting distribution of the EPL. A bubble generator (57), which produces bubbles in the installation area of the workpieces (100), is disposed between the bottom of the bath (53) and the workpieces so as to help form an electroless Cu plating film (40) on each workpiece (100) and so that bubbles from the bubble generator (57) rise up along both sides of each workpiece.

### BACKGROUND OF THE INVENTION

1. Field of the Invention

The present invention relates to manufacturing methods for making wiring circuit boards. More particularly, the invention relates to wiring circuit board manufacturing methods which use electroless Cu plating and to an electroless plating apparatus for manufacturing wiring circuit boards.

2. Description of the Related Art

Organic wiring circuit boards having a mutually laminated structure formed by at least one dielectric layer and at least one conductor layer of high molecular weight material are well known. Such circuits are commonly referred to as multilayer wiring circuit boards and are used for connection of IC, LSI and other chips. Today, most organic wiring circuit boards having ultrafine circuits are manufactured by a “build-up” method which involves stacking a conductor layer and a dielectric layer, one by one, alternately, on a core substrate. In a typical example of the build-up method, a thin base material is first formed by electroless copper (Cu) plating, and a circuit is formed by electrolytic Cu plating using the base conductor.

To form superior circuit elements (both wiring and via conductors) when employing the electrolytic/electroless Cu plating method, a known technique will now be described. In this regard, reference is made to Japanese unexamined patent publication No. 2003-133698 which relates to a technique of electrolytic Cu plating while keeping bubbles in contact with the work surface. In the manufacture of such organic wiring circuit boards, in order to increase productivity, multiple products (wiring circuit boards) are manufactured, in batch, from a single panel. Although multiple products (wiring circuit boards) are obtained from a single panel (workpiece), only those products that pass shipping inspections of an electrical characteristic inspection, among others, are actually shipped as products.

One aspect of the present invention involves the inventive appreciation that rejected products not passing the abovementioned inspections tend to be localized in a specific region in the panel. As a result of intensive studies, it has been found that there is a certain relationship between the thickness variations or fluctuations of the electroless Cu plating film and the location of occurrence of such thickness variations in the rejected products. More specifically, as shown in FIG. 10, which is a schematic representation of a panel 90 of the type referred to above, in the portion thereof closer to the upper end of panel 90, an electroless Cu plating film is formed which has a designed thickness, while in the portion closer to the lower end of panel 90, the thickness of electroless Cu plating film tends to be insufficient. As used herein, the upper and lower portions correspond to upper and lower part of panel 90 when the panel 90 is immersed in an electroless Cu plating liquid.

When the thickness of the electroless Cu plating film is less than the designed value, the following problems may occur. As shown in FIG. 11A, which is a schematic diagram of a via 92, an electroless Cu plating film 94 is formed, albeit very thinly, near the opening of via 92. However, near the boundary of the bottom and the side of via 92, adjacent to a via pad 98, the electroless Cu plating film 94 may not be present at all, depending on the location, particularly in the portion encircled in dashed lines. This portion is shown in FIG. 11B, and as shown in FIG. 11B. When the electrolytic Cu plating is carried out under these circumstances, the resultant formation of the via conductor, indicated at 96, is insufficient, and a problem with there being a good electrical connection between the via conductor 96 and via pad 98 may occur.

### SUMMARY OF THE INVENTION

In light of the foregoing problems, it is hence an object of the invention to provide a manufacturing method for a wiring circuit board which is capable of enhancing the yield and of unifying the electrical characteristics among the products, by reducing the fluctuations in thickness of electroless Cu plating film. It is another object to provide an electroless plating apparatus for executing this manufacturing method.

To solve the problems, there is provided, in accordance with one aspect of the invention, a manufacturing method for a wiring circuit board which comprises:

an electroless Cu plating process comprising setting up of, in an upright position, a plurality of wiring circuit board workpieces as intermediate products during manufacture of the wiring circuit boards while creating gaps between the workpieces so as to permit distribution of an electroless plating liquid,

disposing a bubble generator in a plating bath filled with the electroless Cu plating liquid, said bubble generator being of sufficient extent or spread in a horizontal plane to include a geometrical projection of all of the workpieces onto the horizontal plane within the horizontal extent of the bubble generator in said horizontal plane, and being disposed between the bottom of the plating bath and wiring circuit board workpieces,

injecting bubbles from the bubble generator so that the bubbles rise up along opposed major surfaces of teach of the wiring circuit board workpieces, and

applying an electroless Cu plating film on each wiring circuit board workpiece.

According to the invention, all wiring circuit board workpieces are contacted uniformly by the bubbles, and fresh electroless Cu plating liquid permeates into all parts, thereby decreasing variations or fluctuations of the thickness of the electroless Cu plating film. Moreover, because an electroless Cu plating film is well formed in the vias of the workpieces, the conduction characteristics and connection reliability of the vias are improved. As a result, the number of wiring circuit boards rejected during shipping inspections is decreased. Further, the method used promotes uniformity in the electrical characteristics among the products produced, i.e., from product to product.

The method of the invention is particularly effective when the electroless Cu plating liquid employs Rochelle salt as complexing agent. The electroless Cu plating process preferably forms an electroless Cu plating film having a thickness between about 0.3 μm and 3 μm and this process is preferably followed by an electrolytic Cu plating process carried out by using the electroless Cu plating film as a base conductor for a current feed.

In preferred embodiments, the complexing agent of the electroless Cu plating liquid comprises either Rochelle salt (potassium sodium tartate) or EDTA (ethylene diamine tetra-acetic acid). In this regard, an electroless Cu plating liquid using EDTA has excellent covering properties, but tends to be characterized by relatively large residual stress. On the other hand, an electroless Cu plating liquid using Rochelle salt tends to have smaller residual stress, but is slightly inferior with respect to its covering properties. Considering a process wherein subsequent processing such as solder reflow is used, the residual stress of the plating film is preferably as small as possible. When the thermal history is considered for plating film of large residual stress, it is found that the film is likely to be cracked or flawed.

An electroless Cu plating liquid using EDTA is well suited to forming a relatively thick electroless Cu plating film. However, except for the “full additive” method of forming the circuits only by electroless Cu plating, the electroless Cu plating film applied serves as a base material for electrolytic Cu plating. Hence, for the ease of removal, it is preferable to form a film of a thickness between about 0.3 μm and 3 μm. From a comprehensive standpoint, when forming a circuit in combination with an electrolytic Cu plating process, it is preferable to use an electroless Cu plating liquid using Rochelle salt. However, just using Rochelle salt alone does not solve the problem associated with the slightly inferior covering properties of such a film, but this problem is solved by the method of the invention. Another advantage of electroless Cu plating liquid using Rochelle salt is that deposition of the film takes place at room temperature.

In accordance with another aspect of the invention, a plurality of wiring circuit board workpieces are suspended at equal intervals on a rack. The rack is adapted to be immersed in the plating bath so that the spacing interval of the wiring circuit board workpiece and the bubble generator can be maintained constant. Hence, the distance or spacing between the bubble generator and wiring circuit board workpieces can be easily controlled, so as to ensure that the bubbles will uniformly contact with the wiring circuit board workpieces.

In preferred embodiments, the bubble generator includes bubble ejection holes arranged in rows so as to eject bubbles at an angle to the horizontal. Preferably, bubbles ejected from mutually adjacent rows cross at positions lower than the lower end of the wiring circuit board workpieces, and are caused to flow along both major side surfaces of the wiring circuit board workpieces, by adjusting the relative positions of the bubble generator and the wiring circuit board workpieces. By providing crossing of the bubbles ejected from the bubble generator, the generation of fine bubbles is promoted, and, as a result, the bubbles smoothly climb up along both side surfaces of the wiring circuit board workpieces.

In a specific preferred embodiment, the bubble ejection holes of the bubble generator are arranged in zigzag form so that bubbles ejected from mutually adjacent rows can cross easily.

In some preferred embodiments, the bubble generator is formed by a plurality of bubble generating pipes, and two or more longitudinal rows of bubble ejection holes are formed along each bubble generating pipe. The longitudinal axes of the bubble generating pipes comprising the bubble generator preferably extend parallel to the planes defined by the wiring circuit board workpieces (i.e., parallel to the direction orthogonal to thickness direction of the workpieces). As a result, there is more uniform contact between the bubbles and both side surfaces of each of the wiring circuit board workpieces. This is, of course, beneficial in forming a more uniform plating film.

The particular make-up of wiring circuit boards applicable to the method of the invention is, in general, unimportant, but the method is of substantial advantage when used with a circuit board including a small diameter via, i.e., in which the diameter of the bottom of the via used for providing a conductive connection between the various layers of the circuit board is 55 μm or less in the completed state of the product. In such a case, the wiring circuit board workpieces are integrated (linked) in a plurality of unit workpieces as individual wiring circuit boards. With conventional processes, the plating liquid typically does not permeate into all parts of via holes of small diameter, and the covering properties of the plating film are poor, so that the application of the method of the invention is particularly recommended for wiring circuit boards having via holes of such small diameter.

In accordance with another aspect of the invention, to solve the above-discussed problems, there is provided an electroless plating apparatus for manufacturing wiring circuit boards comprising a plating bath containing electroless plating liquid, a rack for setting up, in an upright position, a plurality of wiring circuit board workpieces as intermediate stage wiring circuit boards, so as to create gaps therebetween to thereby allow distribution of the electroless plating liquid between and around the workpieces, in the plating bath, and a bubble generator, disposed between the wiring circuit board workpieces held by the rack and the bottom of the plating bath, and producing bubbles having sufficient horizontal spread to encompass a perpendicular geometrical projection of all of the workpieces onto a horizontal plane, said bubble generator including bubble ejection holes of a density sufficient to enable the bubbles to come into contact with the major surfaces of all of wiring circuit board workpieces.

Because the electroless plating apparatus of the invention includes a bubble generator having bubble ejection holes of a density sufficient to enable the bubbles to come into contact with the major surfaces of all of the wiring circuit board workpieces, the bubbles will uniformly contact all wiring circuit board workpieces. Because fresh electroless plating liquid can permeate into all of the small parts of the workpieces, variations or fluctuations in the thickness of the electroless plating film formed on the wiring circuit board workpieces are minimized.

Further features and advantages of the present invention will be set forth in, or apparent from, the detailed description of preferred embodiments thereof which follows.

### BRIEF DESCRIPTION OF THE DRAWINGS

FIG. 1 is a cross-sectional view of an exemplary wiring circuit board;

FIG. 2 is a schematic plan view of a wiring circuit board workpiece;

FIG. 3 is a series of cross section views showing sequential steps in a manufacturing process for making wiring circuit boards, in accordance with a preferred embodiment of the invention;

FIG. 4 is a schematic cross-sectional view of apparatus for carrying out an electroless Cu plating process in accordance with a preferred embodiment of the invention;

FIG. 5 is a schematic exploded perspective view showing the relative orientation of the wiring circuit board workpieces and bubble generator shown in FIG. 4;

FIG. 6 is a cross-sectional view used in explanation of a preferred bubble ejection mode;

FIG. 7 is a schematic plan view of a bubble generator in accordance with one preferred embodiment of the invention;

FIG. 8 is a plan view drawn to an enlarged scale of a series of bubble ejection holes;

FIG. 9 is a cross-sectional view taken generally along line A-A of FIG. 8 and drawn to an enlarged scale;

FIG. 10 is a graph used in explaining the thickness distribution of the electroless Cu plating film;

FIGS. 11A and 11B are cross section views used in explanation of defects caused by fluctuations in the thickness of the electroless Cu plating film;

FIG. 12 is a schematic plan view of a further embodiment of the electroless plating apparatus of FIG. 4 showing the relative positions, in plan, of the racks and the bubble generator;

FIG. 13 is a diagram used in explaining the measuring positions for measuring the electroless Cu plating film thickness;

FIG. 14 is a graph of the thickness measuring results with respect to an electroless Cu plating film formed by the method of the invention;

FIG. 15 is a graph showing results of a comparative example.

### DESCRIPTION OF THE PREFERRED EMBODIMENTS

Referring to the accompanying drawings, preferred embodiments of the invention will now be described.

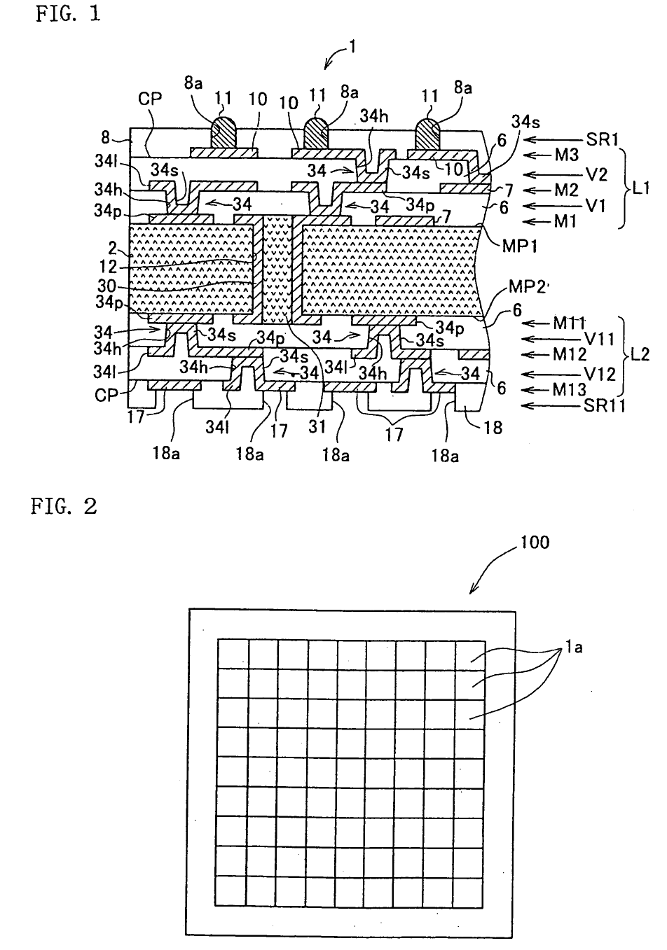

FIG. 1 shows, schematically, a cross-sectional view of a wiring circuit board 1 produced using a preferred embodiment of the invention. The wiring circuit board 1 comprises core conductor layers M1, M11 (also referred to as conductor layers) forming wiring metal layers of a specified pattern on both sides of a plate or planar core 2. Core 2 is preferably made of heat resistant resin board (for example, bismaleimide-triazine resin board), fiber reinforced resin board (for example, glass fiber reinforced epoxy resin) or the like. Core conductor layers M1, M11 are preferably formed as surface conductor patterns covering the majority of the surface of a plate or planar core 2, and are used as a power source layer or a grounding (ground) layer.

A through-hole 12 is formed in the plate core 2 by drilling or piercing, and a through-hole conductor 30 is formed on the inner wall of the through-hole for providing electrical communication, i.e., an electrical connection, between the core conductor layers M1, M11. The through-hole 12 is preferably filled up with a resin filler 31 of epoxy resin or the like.

On the outer surfaces of core conductor layers M1, M11, first dielectric layers (build-up layers) V1, V11, preferably made of a thermosetting resin composition 6, are formed. Further, on the surfaces of layers V1, V11, first conductor layers M2, M12, comprising metal wiring 7, are formed by Cu plating. The core conductor layers M1, M11 and first conductor layers M2, M12 are connected together by means of a via 34.

Similarly, on the outer surfaces of first conductor layers M2, M12, second dielectric layers (build-up layers) V2, V12, made of a thermosetting resin composition 6, are formed. Further, on the surfaces of layers V2, V12, second conductor layers M3, M13, comprising metal terminal pads 10, 17, are formed. The first conductor layers M2, M12 and second conductor layers M3, M13 are electrically connected together by means of a via 34.

The via 34 includes a via hole 34h, a via conductor 34s provided on the inner circumferential surface of hole 34h, a via pad 34p provided to communicate with the via conductor 34s at the bottom side thereof, and a via land 34l projecting outwardly from the peripheral edge of the opening defined by via conductor 34s at the opposite side of via hole 34h from the via pad 34p.

With the construction described above, on a first principal surface MP1 of the plate core 2, a first wiring laminate L1 is comprised of core conductor layer M1, first dielectric layer V1, first conductor layer M2, second dielectric layer V2, and second conductor layer M3. Similarly, on a second principal surface MP2 of the plate core 2, a second wiring laminate L2 is comprised of core conductor layer M11, first dielectric layer V11, first conductor layer M12, second dielectric layer V12, and second conductor layer M13. In both of these two laminates L1 and L2, the dielectric layers and conductor layers are laminated alternately so that a first principal surface CP is formed by a respective dielectric layer 6, and plural metal terminal pads 10, and 17 are respectively formed on the corresponding principal surface CP. The metal terminal pad 10 on the side of the first wiring laminate L1 comprises a solder land 10 for “flip chip” connection of an integrated circuit chip or the like. The metal terminal pad 17 on the side of the second wiring laminate L2 is used as reverse land (PGA pad, BGA pad) for connecting the wiring circuit board to a mother board, or the like, by pin grid array (PGA) or ball grid array (BGA).

The solder land 10 is preferably arrayed in a lattice pattern and is located nearly in the center of first principal surface of the wiring circuit board 1. Solder land 10 together with solder bumps 11 formed thereon form chip mounting parts. A reverse land 17 in the second conductor layer M13 is also arrayed in a lattice pattern.

On the second conductor layers M3, M13, solder resist layers 8, 18 (SR1, SR11) made of a photosensitive or thermosetting resin composition are formed. In order to expose the solder land 10 or reverse land 17, openings 8a, 18a are formed in one by one correspondence with each land. The solder bump 11 of solder resist layer 8 formed on the side of the first wiring laminate L1 can be comprised of solder which contains substantially no Pb such as, for example, Sn—Ag, Sn—Cu, Sn—Ag—Cu, or Sn—Sb. On the other hand, the metal terminal pad 17 on the side of the second wiring laminate L2 is formed so as to extend into the opening 18a in the solder resist layer 18 and thus be exposed therein.

A preferred manufacturing method of wiring circuit board 1 will now be described.

First, through-hole 12 is formed by drilling through or otherwise piercing the heat resistant resin board (for example, bismaleimide-triazine resin board) or fiber reinforced resin board (for example, glass fiber reinforced epoxy resin) forming plate core 2. By using pattern plating, core conductor layers M1, M11 and through-hole conductor 30 are formed, and the through-hole 12 is filled with resin filler 31.

After roughening the core conductor layers M1, M11, the resin film is laminated and cured so as to cover the core conductor layers M1, M11, and first dielectric layers V1, V11 are formed (preferably using a dielectric layer forming process). The resin film is formed of thermosetting resin composition mixed with silica filler or the like. On the plate core 2, core conductor layers M1, M11 and first dielectric layers V1, V11 are laminated in this order or sequence, and the first dielectric layers V1, V11 are irradiated with laser light on the principal surfaces thereof, and via holes 34h are formed in a specified pattern (preferably using a laser piercing process). Using a pattern plating process employing photolithography, first conductor layers M1, M12 are formed in the via holes 34h together with via conductor 34s.

By repeating this process, first wiring laminate L1 and second wiring laminate L2 are formed. Further solder resist layers SR1, SR11 are also formed, conductor layers M3, M13 which are exposed by the openings 8a, 18a of the solder resist layers SR1, SR11 are plated with Ni/Au, and terminal pads 10, 17 are thus obtained. After the Ni/Au plating process, openings 8a of the solder resist layer SR1 are filled with lead-free solder paste such as Sn—Ag—Cu, and reflow process is executed. As a result, respective solder bumps 11 are formed on the terminal pad 10.

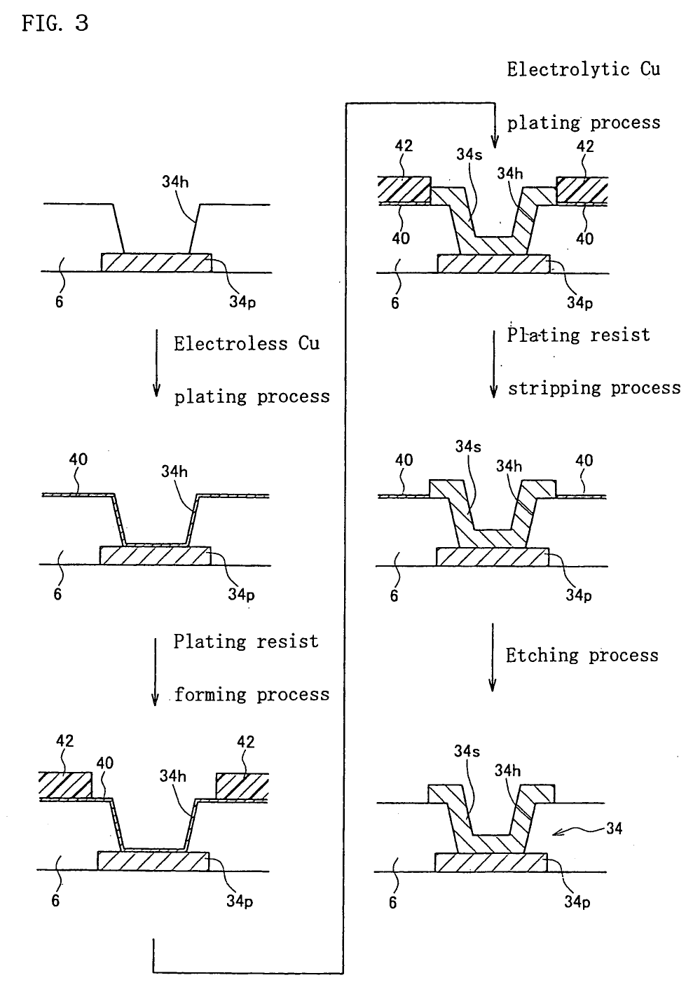

The pattern plating process used in forming core conductor layers M1, M11, first conductor layers M2, M12, second conductor layers M3, M13, and through-hole conductor 30 and via conductor 34s is executed as follows. Generally speaking, as shown in FIG. 3, the pattern plating process of this embodiment includes an electroless Cu plating process, a plating resist forming process, an electrolytic Cu plating process, a plating resist stripping process, and an etching process. The example in FIG. 3 is concerned with forming of a via 34.

Considering the process in more detail, as shown in FIG. 3, a resin film is adhered to the principal surface of the core substrate, and dielectric layer 6 is formed. The dielectric layer 6 is irradiated with laser to form via hole 34h. Next a desmearing process is used for removing resin residue from the via hole 34h, along with water washing or another pretreatment process, followed by an electroless Cu plating process.

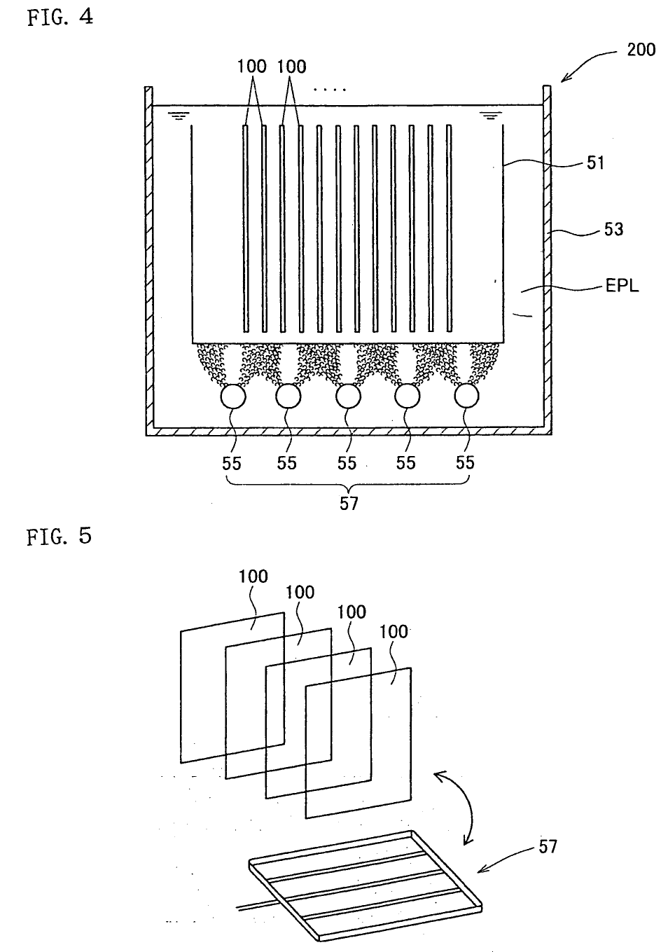

Before further considering the process of FIG. 3, it is noted that, in general, as shown in FIG. 1, the wiring circuit board 1 is manufactured as a linked wiring circuit board linking plural wiring circuit boards 1. Accordingly, the manufacturing process of wiring circuit board 1 is carried out as shown in FIG. 2, on wiring circuit board workpieces 100 linking multiple wiring circuit boards 1a (unit workpieces) during manufacture. The electroless Cu plating process used in forming circuit elements such as via 34 of FIG. 3 is executed by using an electroless plating apparatus 200 shown in FIG. 4.

As illustrated in FIG. 4, the electroless plating apparatus 200 comprises a plating bath 53 containing electroless Cu plating liquid EPL, a rack 51 for holding a plurality of wiring circuit board workpieces 100 in upright position, and a bubble generator 57 positioned between the wiring circuit board workpieces 100 and the bottom of plating bath 53. The rack 51 holds the wiring circuit board workpieces 100. The wiring circuit board workpieces 100 are arranged in an upright position in the rack 51, which is preferably made of stainless steel, metal or ceramic material, so as to leave suitable gaps so as to permit proper distribution of the electroless Cu plating liquid EPL. The workpieces 100 put into the plating bath 53 together with the rack 51 in the same upright position. As a result, the plurality of wiring circuit board works 100 are immersed in the plating bath 53 filled with electroless Cu plating liquid EPL.

The bubble generator 57 is positioned at the bottom of the plating bath 53, and more specifically, beneath the wiring circuit board workpieces 100 held by the rack 51, and is of sufficient extent to spread in the horizontal direction so as to provide bubbling over the entire region of the wiring circuit board workpieces 100. The bubble generator 57 ejects the bubbles so that the bubbles may rise up by climbing up on both sides of the individual wiring circuit board workpieces 100. Since the wiring circuit board workpieces 100 all contact the bubbles uniformly, the circulation of electroless Cu plating liquid EPL is improved, and fluctuations in the thickness of electroless Cu plating film 40 can be eliminated or suppressed.

Preferably, the electroless Cu plating liquid EPL contains a copper salt (CuSO₄, etc.), a reducing agent (HCHO, etc.), a complexing agent (Rochelle salt, EDTA, etc.), a pH regulating agent (NaOH, KOH, etc.), and other additives (polyethylene glycol, dipyridyl, etc.). In the embodiment under consideration, since the circuit is used in combination with electrolytic Cu plating (which is referred to as semi-additive method), the electroless Cu plating film 40 is formed to have a thickness between about 0.3 μm and 3 μm so as to be easily removed later. Rochelle salt is preferably used as complexing agent for electroless Cu plating liquid EPL in forming a thin film. The electroless Cu plating liquid EPL using Rochelle salt has many advantages; for example, the plating process can be executed at room temperature, and any residual stress in the formed electroless Cu plating film 40 is small.

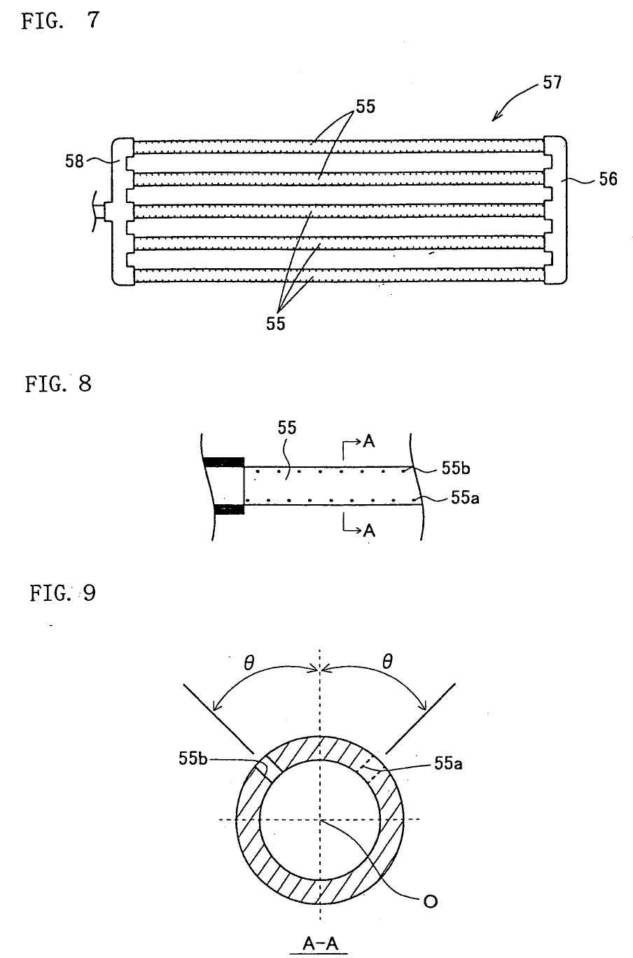

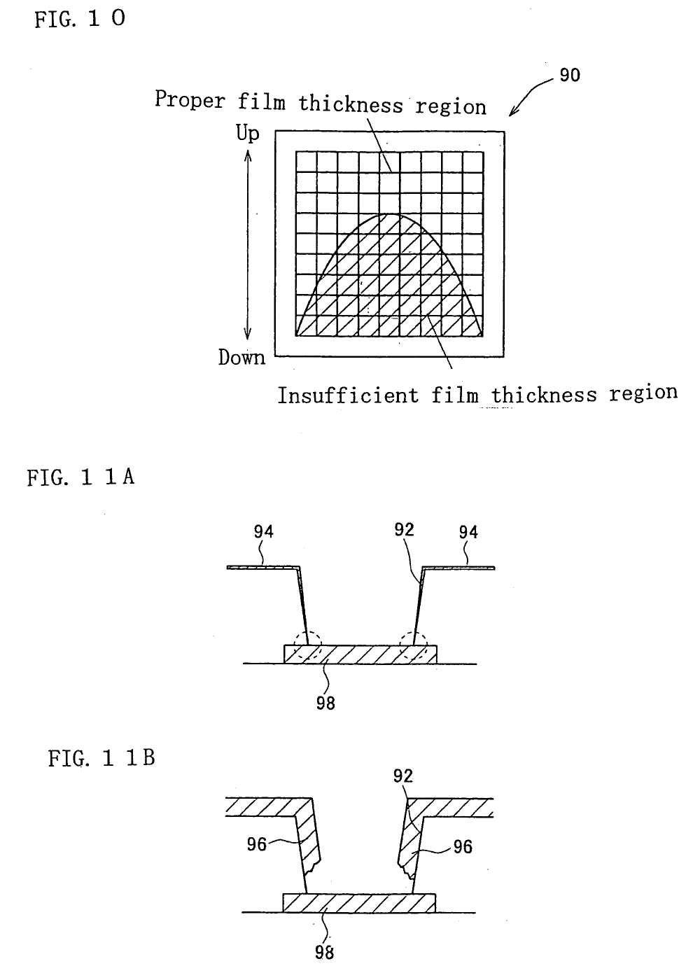

The bubble generator 57 will now be described in more detail. As shown in FIG. 4, the bubble generator 57 is positioned inside of the outer edges of the rack 51 which is used in suspending multiple wiring circuit board workpieces 100 at equally spaced intervals. The bubble generator 57 includes bubble ejection holes 55a, 55b (see FIG. 8) of a density such as to provide contact between the bubbles and the surfaces of all wiring circuit board workpieces 100, so that the bubbles sufficiently permeate into all wiring circuit board workpieces 100 held by the rack 51. In addition, spacing is provided between the wiring circuit board workpieces 100 and the bubble generator 57 such that a bubble group ejected from the bubble generating pipes 55 (FIG. 7) of bubble generator 57 initially spread outwardly sufficiently in the horizontal direction to provide coverage of workpieces 100, and then rises up along both sides of the wiring circuit board workpieces 100.

As shown in the schematic plan view of FIG. 7, the bubble generator 57 includes plural (five) bubble generating pipes 55 arranged in parallel, and the opposite ends of the pipes 55 are linked by two assembly pipes 56, 58. Further, in executing the electroless Cu plating process, as shown in FIG. 5, the longitudinal axes of the bubble generating pipes 55 of the bubble generator 57 extend parallel to the principal surfaces (front and reverse side) of the wiring circuit board workpieces 100. As a result, bubbles are smoothly ejected into the gaps between the mutually adjacent wiring circuit board workpieces 100. As an alternative to the bubble generator 57 shown in FIG. 7, which uses bubble generating pipes 55, a bubble generator in the form of a hollow plate having multiple fine pores provided in one major surface thereof may be also used. Moreover, the structure for generating bubbles may be formed integrally with the plating bath unit 53 at the bottom of the plating bath unit 53.

As shown in an enlarged scale in FIG. 8, in the individual bubble generating pipes 55 for comprising the bubble generator 57, two rows of bubble eject holes 55a, 55b are formed together in a zigzag pattern along the longitudinal axis of the corresponding pipe 55. The bubble generating pipes 55 are preferably circular in section. Therefore, the peripheral angular position of one row of bubble eject holes 55a and the peripheral angular position of other row of bubble eject holes 55b are spaced from each other. More specifically, as shown in the cross-sectional view of FIG. 9, an angle θ is formed between the axis of bubble eject hole 55a and the center ◯ of bubble generating pipe 55 with respect to the perpendicular. Similarly, an angle θ is also formed between the other bubble eject hole 55b and the center ◯ of bubble generating pipe with respect to the perpendicular. The angle of inclination θ is preferably set to be around 45 degrees. As a result, the bubble generator 57 ejects bubbles at an angle which is inclined obliquely to the horizontal.

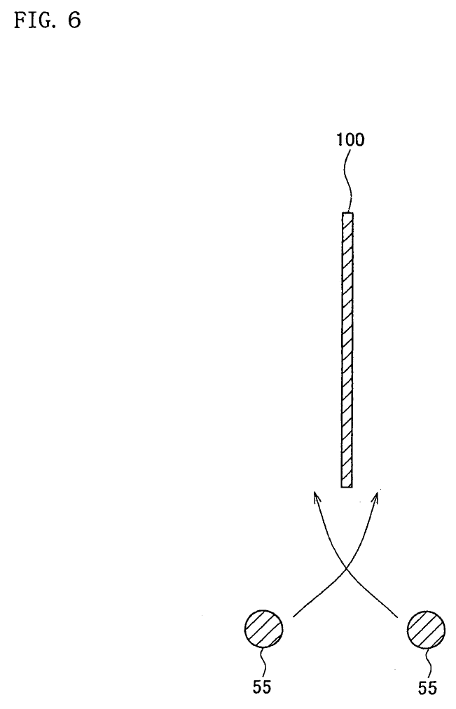

With this arrangement, by adjusting the spacing between the bubble generator 57 and the wiring circuit board workpieces 100 in the perpendicular direction (i.e., vertically in FIGS. 4 and 6) to more than a specified value, as shown in FIG. 4 and FIG. 6, the bubbles ejected from the mutually adjacent bubble generating pipes 55 cross each other beneath the lower end of the associated wiring circuit board workpieces 100. As a result, even using a smaller number of bubble generating pipes 55 than the number of wiring circuit board workpieces 100 arranged in the rack 51, the electroless Cu plating process can be carried out while still providing uniform contact between the bubbles and all of the wiring circuit board workpieces 100. Preferably, one bubble generating pipe 55 is provided between each pair of adjacent wiring circuit board workpieces 100 or the number of rows of bubble ejection holes provided is the same as the number of wiring circuit board workpieces 100. However, considering factors such as productivity, installation space and installation cost, the mutual interval between adjacent bubble generating pipes 55 is preferably greater (wider) than the spacing between wiring circuit board workpieces 100 as in the embodiment of FIG. 4.

In this embodiment, the gas supplied to the bubble generator 57 is preferably air, but if an excessive rise in the dissolved oxygen concentration due to the agitation of the air becomes a problem, another gas may be used for agitation, such as, for example, nitrogen, or air may be diluted in nitrogen, and a diluted gas of a lowered oxygen concentration may be used for agitation. In another alternative implementation, bubbles may be ejected intermittently rather than continuously while monitoring the dissolved oxygen concentration.

Returning again to FIG. 3., after the electroless Cu plating process, a plating resist 42 is patterned so as to expose a thick forming region for forming a thicker Cu plating than the electroless Cu plating film 40 (in accordance with the plating resist forming process). After forming the plating resist 42, the electrolytic Cu plating process is executed using the electroless Cu plating film 40 as base material for a current feed. As a result of this process, a via conductor 34s is formed in the via hole 34h, as shown.

After the electrolytic Cu plating process, the plating resist 42 is removed (in accordance with the plating resist stripping process). When the plating resist 42 is removed, the electroless Cu plating film 40 is exposed in the non-forming region of the electrolytic Cu plating, and by soft etching (i.e., etching over a short period of time), the electroless Cu plating film 40 is removed. As a result, the wires are mutually separated in terms of direct current flow.

### EXAMPLE

The following experiment was conducted in order to confirm the effects produced by the invention.

a. The Electroless Plating Apparatus

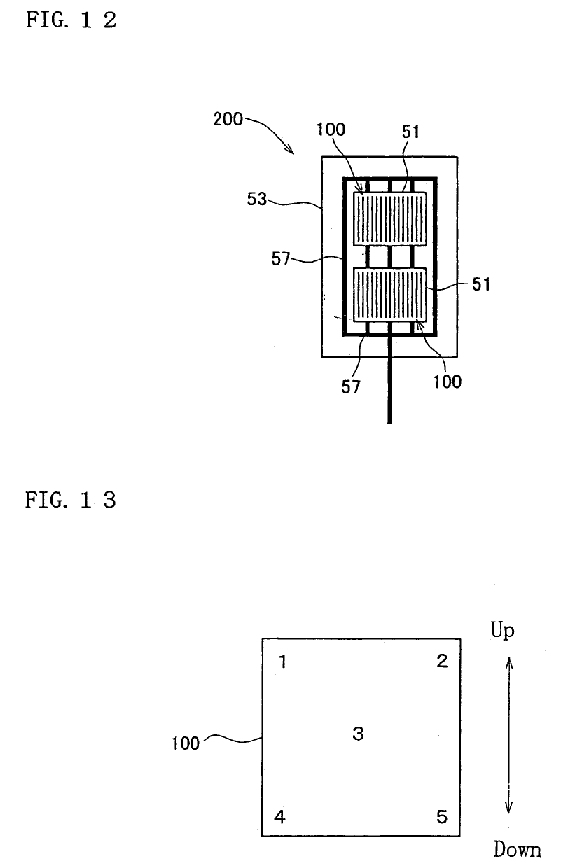

The experiment was conducted by using an electroless plating apparatus 200 shown in a plan view in FIG. 12. The elements indicated in the thick line in the plating bath 53 is the bubble generator 57 described above in connection with FIG. 7. During the execution of the plating process, the air feeding rate at which air is fed into the bubble generator 57 was adjusted by mass flow controller (not shown).

b. The Wiring Circuit Board Workpiece

As shown in FIG. 12, the rack 51 was disposed immediately above the bubble generator 57. The wiring circuit board workpieces 100 were suspended at positions indicated by thin lines inside of the rack 51. For all of the wiring circuit board workpieces 100, the principal substrate surface extends parallel to the longitudinal direction in FIG. 12 and perpendicular to the plane of the bubble generator 57. For the bubble generator 57 shown in FIG. 12, two racks 51, 51 were disposed in side by side relation. In each rack 51, sixteen wiring circuit board workpieces 100 were disposed. The wiring circuit board workpieces 100 were workpieces formed in the process prior to the forming of a via, by adhering only a resin film (a “build-up” film produced by Ajinomoto) for the wiring circuit board on a dummy substrate of the dimensions of 450 mm×430 mm.

c. The Plating Conditions

In this example, the composition of electroless Cu plating liquid is as follows.
Cu conc. 2.5+−0.3 (g/liter)
HCHO conc. 2.0+−0.5 (g/liter)
NaOH conc. 1.5+−0.5 (g/liter)
Specific gravity Max. 1.08

Rochelle salt was used as complexing agent. During the electroless Cu plating process, the temperature of plating liquid was maintained at 36 degrees C. by using a heater. In the electroless Cu plating process, the thickness of electroless Cu plating film was adjusted to about 1.0 μm. During this electroless Cu plating process, it was confirmed by visual observation that all wiring circuit board workpieces 100 were in uniform contact with the bubbles.

d. Measurement Results with Respect to the Thickness of the Electroless Cu Plating Film

After the electroless Cu plating process, the rack 51 was quickly lifted from the plating bath 53, and wiring circuit board workpieces 100 were washed in water. In each individual wiring circuit board workpiece 100, the plating film thickness was measured at five different positions which are specified in FIG. 13 at 1, 2, 3, 4, and 5, and the distribution of film thickness for the workpieces was investigated.

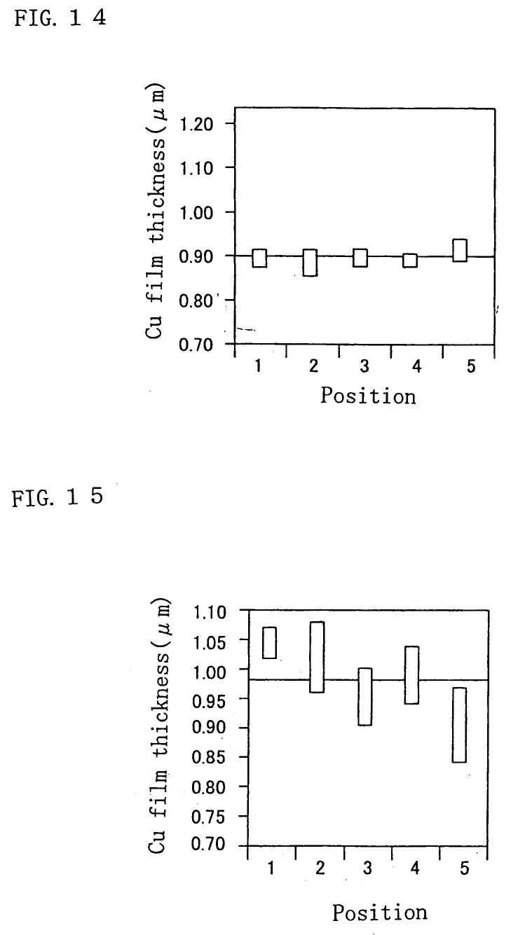

The results of this investigation are shown in FIG. 14. The graph in FIG. 14 shows that all results measured at all positions are included in the range indicated by the square. As shown in FIG. 14, with the method of this embodiment of the invention, thickness variations or fluctuations for the electrolytic Cu plating film were small, whether at the same position or at different positions. The standard deviation was 0.026. As shown in FIG. 14, there was no evident or significant difference in film thickness in the vertical direction of the wiring circuit board workpieces 100.

e. A Comparative Example

In this example, all bubble generators 57 were removed from the plating apparatus 200 of FIG. 12, and mixing screws (not shown) were installed instead for use as the plating liquid agitator. Under the same conditions as set forth above for the procedure of the above-described embodiment with the exception that the plating liquid was agitated slowly by the agitator screws, electroless Cu plating films were formed on the wiring circuit board workpieces 100. After forming the electroless Cu plating films, the film thickness was measured using the same procedure as described above. The results are shown in FIG. 15.

As shown in FIG. 15, in the method of the comparative example which provided for merely agitating the plating liquid, the variations or fluctuations in the thickness of the electroless Cu plating film were large. The standard deviation was 0.086. As is shown in FIG. 15, there was an evident tendency toward large film thicknesses at positions 1 and 2 (FIG. 13) close to the upper end of the wiring circuit board workpieces 100, and small film thicknesses at position 5 close to the lower end.

Although the invention has been described above in relation to preferred embodiments thereof, it will be understood by those skilled in the art that variations and modifications can be effected in these preferred embodiments without departing from the scope and spirit of the invention.

What is claimed:

1. A manufacturing method for manufacturing wiring circuit boards comprising:
an electroless Cu plating process comprising setting up a plurality of wiring circuit board workpieces as intermediate products during manufacture of the wiring circuit boards in an upright position while creating gaps between the workpieces so as to permit distribution of an electroless plating liquid between the workpieces;
disposing a bubble generator in a plating bath filled with the electroless Cu plating liquid of sufficient extent in a horizontal plane to include a geometrical projection of all of the workpieces within the horizontal extent of the bubble generator in said horizontal plane, and being disposed between the bottom of the plating bath and the wiring circuit board workpieces;
injecting bubbles from the bubble generator so that bubbles rise up along opposed major surfaces of each of said wiring circuit board workpieces, and
applying an electroless Cu plating film onto each wiring circuit board workpiece.

2. The manufacturing method of claim 1, wherein the electroless Cu plating liquid includes Rochelle salt as complexing agent, wherein the electroless Cu plating film has a thickness of between about 0.3 μm and 3 μm and wherein the electroless Cu plating process is followed by an electrolytic Cu plating process carried out using the electroless Cu plating film as abase conductor for a current feed.

3. The manufacturing method of claim 1, wherein the plurality of wiring circuit board workpieces are disposed at equally spaced intervals on a rack, and the rack is immersed in the plating bath so that the spacing interval of the wiring circuit board workpieces relative to the bubble generator is maintained constant.

4. The manufacturing method of claim 1, wherein the bubble generator includes bubble ejection holes arranged in rows so as to eject bubbles at an angle to said horizontal plane, and wherein bubbles ejected from mutually adjacent rows are carried to cross at positions lower than the lower ends of the wiring circuit board workpieces, and to flow along both major side surfaces of the wiring circuit board workpieces.

5. The manufacturing method of claim 4, wherein the flow of the ejected bubbles is controlled by adjusting the relative positions of the bubble generator and the wiring circuit board workpieces.

6. The manufacturing method of claim 4, wherein the bubble ejection holes are arranged in a zigzag pattern.

7. The manufacturing method of claim 1, wherein the bubble generator comprises a plurality of bubble generating pipes each having a longitudinal axis and each including at least two rows of bubble ejection holes formed along the longitudinal axis thereof, and wherein the longitudinal axis of each of the bubble generating pipes extends parallel to the planes of the wiring circuit board workpieces.

8. The manufacturing method of claim 1, wherein the wiring circuit boards include vias having a bottom diameter of 55 μm or less.

9. An electroless plating apparatus for manufacturing wiring circuit boards, said apparatus comprising:
a plating bath for containing electroless plating liquid,
a rack for a plurality of wiring circuit board workpieces comprising intermediate stage wiring circuit boards, said workpieces being immersed in the plating bath and said rack supporting each of said workpieces in an upright position so as to create gaps therebetween allowing distribution of the electroless plating liquid between the workpieces in the plating bath; and
a bubble generator disposed between the wiring circuit board workpieces supported by the rack and the bottom of the plating bath, and producing bubbles having sufficient horizontal spread to encompass a geometric projection of all of the workpieces onto a horizontal plane, and said bubble generator including bubble ejection holes of a density sufficient to enable the bubbles to come into contact with opposed major surfaces of all of the wiring circuit board workpieces.
